(19) United States
(12) Patent Application Publication
(10) Pub. No.: US 2026/0305081 A1
(43) Pub. Date: Oct. 1, 2026

(54) DISPLAY DEVICE

(71) Applicant: LG Display Co., Ltd., Seoul (KR)

(72) Inventors: Sung Soo PARK, Paju-si (KR); Eun Hyung LEE, Paju-si (KR); Hyun Jun PARK, Paju-si (KR)

(21) Appl. No.: 19/431,988

(22) Filed: Dec. 23, 2025

(30) Foreign Application Priority Data
Mar. 31, 2025 (KR) 10-2025-0041362

(51) Int. Cl. H10K 59/122; H10K 101/30

(52) U.S. Cl. CPC H10K 59/122; H10K 2101/30

(57) ABSTRACT

A display device including a substrate that includes a display area including first and second areas and a non-display area outside the display area, a plurality of anodes disposed in the first area, the anodes being spaced apart from each other, an intermediate layer disposed on the plurality of anodes, the intermediate layer disposed over an entirety of the display area, a cathode disposed in the first area to be opposite the plurality of anodes with the intermediate layer interposed therebetween, and a pattern definition layer disposed on the intermediate layer in the second area, the pattern definition layer being in contact with a side surface of the cathode.

### CROSS REFERENCE TO RELATED APPLICATION

This application claims priority from and the benefit of Korean Patent Application No. 10-2025-0041362, filed on Mar. 31, 2025, which is hereby incorporated by reference for all purposes as if fully set forth herein.

### BACKGROUND

### Field

Embodiments of the invention relate generally to a display device including a transmission part in addition to an emission part.

### Discussion of the Background

With the advancement of the information society, the demand for display devices for displaying images is increasing in various forms.

Display devices may implement image display, for example, by including light emitting elements.

The above information disclosed in this Background section is only for understanding of the background of the inventive concepts, and, therefore, it may contain information that does not constitute prior art.

### SUMMARY

Display devices according to embodiments of the invention are capable of improving the sensing sensitivity of a sensing member disposed under the substrate by implementing a transparent display that enables visibility of an image or an object located under a substrate. The display device has a cathode provided on the substrate so as not to overlap a pattern definition layer, thereby increasing the transmittance of a transmission part where the pattern definition layer is disposed. Thus, the display device is capable of improving transmittance through the selective provision of the cathode while simultaneously preventing an increase in drive voltage or changes in current density.

Additional features of the inventive concepts will be set forth in the description which follows, and in part will be apparent from the description, or may be learned by practice of the inventive concepts.

A display device according to an embodiment of the invention includes a substrate including a display area including a first area and a second area and a non-display area outside the display area; a plurality of anodes disposed in the first area, the plurality of anodes being spaced apart from each other; an intermediate layer disposed on the plurality of anodes, the intermediate layer disposed over an entirety of the display area; a cathode disposed in the first area to be opposite the plurality of anodes with the intermediate layer interposed therebetween and a pattern definition layer disposed on the intermediate layer in the second area, the pattern definition layer being in contact with a side surface of the cathode.

The intermediate layer may include a plurality of layers, and the uppermost layer of the intermediate layer may be in contact with the cathode and the pattern definition layer and may include an electron-transportable organic host and a metal dopant.

The organic host may be included in the uppermost layer of the intermediate layer as the main material, such that an amount of the organic host in the uppermost layer of the intermediate layer is greater than an amount of the metal dopant in the uppermost layer of the intermediate layer.

The metal dopant may be included in the uppermost layer of the intermediate layer in a range of substantially 0.001 wt % to substantially 10 wt %, and the organic host may be included in the uppermost layer of the intermediate layer in a range of substantially 90 wt % to substantially 99.999 wt %.

The organic host in the uppermost layer of the intermediate layer may have a LUMO energy level of substantially −3.5 eV to substantially −2.0 eV, and the uppermost layer of the intermediate layer may have a LUMO energy level of substantially −3.3 eV to −2.0 eV.

The cathode may have a work function of substantially 4.0 eV or less, and the work function of the cathode may be equal to or different by substantially 1 eV or less from an absolute value of the LUMO energy level of the uppermost layer of the intermediate layer.

The cathode may be a metal or a metal alloy including at least one of silver (Ag), gold (Au), platinum (Pt), palladium (Pd), copper (Cu), magnesium (Mg), aluminum (Al), titanium (Ti), tungsten (W), and molybdenum (Mo); and a work function of the cathode may be equal to or different from an absolute value of a LUMO energy level of the uppermost layer of the intermediate layer by substantially 1 eV or less.

The metal dopant may include an alkali metal or an alkaline earth metal having a work function of substantially 3.0 eV or less.

The pattern definition layer may not overlap the first area, and surface energy of the uppermost layer of the intermediate layer at the first area exposed from the pattern definition layer may be greater than surface energy of the pattern definition layer.

The organic host may include phenanthrolinyl or phenanthrollinylene.

The intermediate layer may include a hole injection layer, a hole transport layer, and an electron transport layer. A light emitting layer may be further provided in at least the first area between the hole transport layer and the electron transport layer. The electron transport layer may be the uppermost layer of the intermediate layer.

The intermediate layer may include two or more light emitting stacks and a charge generation layer disposed between adjacent two light emitting stacks. Each of the two or more light emitting stacks may include a hole transport layer, a light emitting layer, and an electron transport layer. The electron transport layer of the light emitting stack closest to the cathode may be the uppermost layer of the intermediate layer.

The intermediate layer may include two or more light emitting stacks and a charge generation layer provided between adjacent two light emitting stacks. Each of the two or more light emitting stacks may include a hole transport layer and an electron transport layer. A light emitting layer may be provided between the hole transport layer and the electron transport layer to correspond to different emission parts two-dimensionally spaced apart from each other in the first area. The electron transport layer of the light emitting stack closest to the cathode may be the uppermost layer of the intermediate layer.

The display device may further include a hole blocking layer disposed between the light emitting layer and the electron transport layer, the hole blocking layer including a different electron-transportable material from the organic host.

The display device may further include a capping layer disposed on the pattern definition layer and the cathode.

The display device may further include a sensor member arranged under the substrate to correspond to the second area and a thin film transistor arranged in the first area and between the substrate and each of the plurality of anodes.

The first area may further include a bank exposing a plurality of emission parts while covering an edge of each of the plurality of anodes.

The cathode may be integral in the first area, and overlap a bank located over an entirety of the plurality of anodes and a bank between the plurality of anodes.

The pattern definition layer may be disposed in the display area as an island shape, and the cathode may be disposed in the display area as a matrix shape excluding the pattern definition layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a plan view showing a display device according to an embodiment of the invention.

FIG. 2 is an enlarged views showing areas A and B of FIG. 1.

FIG. 3 is a cross-sectional view taken along line I-I′ of FIG. 2.

FIG. 4A, FIG. 4B, FIG. 4C, and FIG. 4D are cross-sectional views respectively showing ST1 and ST2 of FIG. 3 according to embodiments of the invention.

FIG. 5A and FIG. 5B are schematic cross-sectional views of areas A and B, respectively, of FIG. 1, related to light propagation.

FIG. 6A and FIG. 6B are drawings showing the state in which a metal dopant is bound to an organic host in the uppermost layer of an intermediate layer.

FIG. 7 is an equivalent circuit diagram of a subpixel provided in an active area of the display device according to an embodiment of the invention.

FIG. 8 is a plan view showing a display device according to another embodiment of the invention.

FIG. 9 and FIG. 10 are schematic cross-sectional views showing an emission part and a transmission part in display devices according to various embodiments of the invention.

FIG. 11 is a graph showing the I-V characteristics of first and second experimental examples.

FIG. 12 is a graph showing the luminance characteristics relative to current density of the first and second experimental examples.

FIG. 13 is a graph showing the transmittance of third and fourth experimental examples for comparison.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to cross-sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

In construing a component or numerical value, the component or the numerical value is to be construed as including an error or tolerance range even where no explicit description of such an error or tolerance range is provided.

Features of various embodiments of the invention can be partially or overall coupled to or combined with each other, and can be variously inter-operated with each other and driven technically as those skilled in the art can sufficiently understand. The embodiments of the invention can be carried out independently from each other, or can be carried out together in a co-dependent relationship.

As used herein, the term “LUMO (lowest unoccupied molecular orbital) energy level” and “HOMO (highest occupied molecular orbital) energy level” of a layer refer to the LUMO energy level and HOMO energy level of a material that occupies most of a weight ratio of the layer, for example, a host material, unless the context clearly mentions that the LUMO energy level and the HOMO energy level mean the LUMO energy level and HOMO energy level of a dopant material with which the layer is doped, respectively.

Here, the HOMO energy level is obtained by measuring the voltage corresponding to a first peak at which electrons are discharged from a target material through cyclic voltammetry (CV) while comparing with a reference material whose HOMO energy level is known. For example, the HOMO energy level of a substance may be measured based on a substance whose oxidation potential and reduction potential are known.

In the following description, “a host” among materials in a certain layer accounts for a major amount. Relatively, a dopant accounts for a minor amount in the certain layer. For example, if the certain layer comprises a host and a dopant, then the dopant can be included in an amount less than 30% by weight in the certain layer. In this case, the other material excluding the dopant can be the host. In a layer, the host and the dopant can include at least one material, independently.

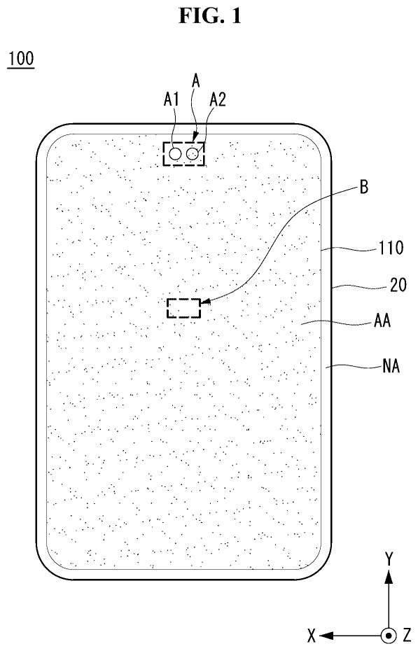

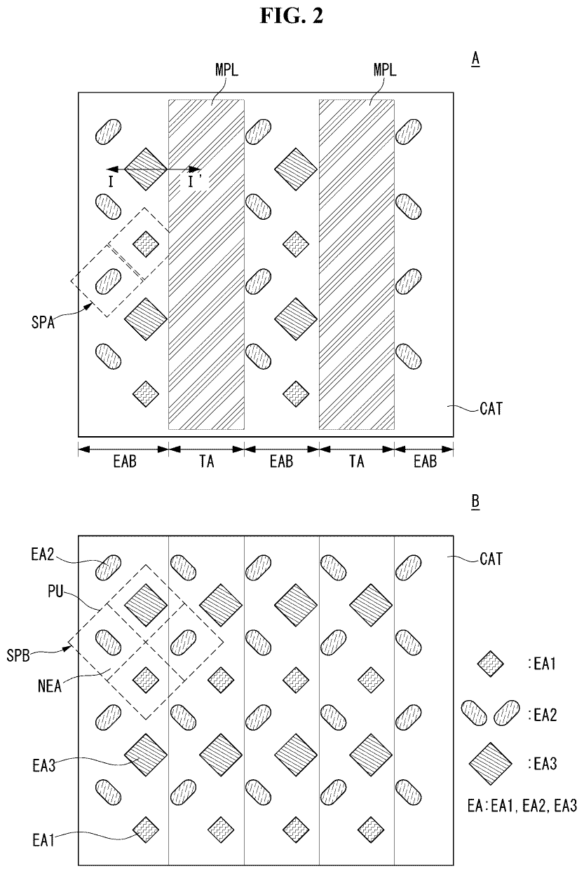

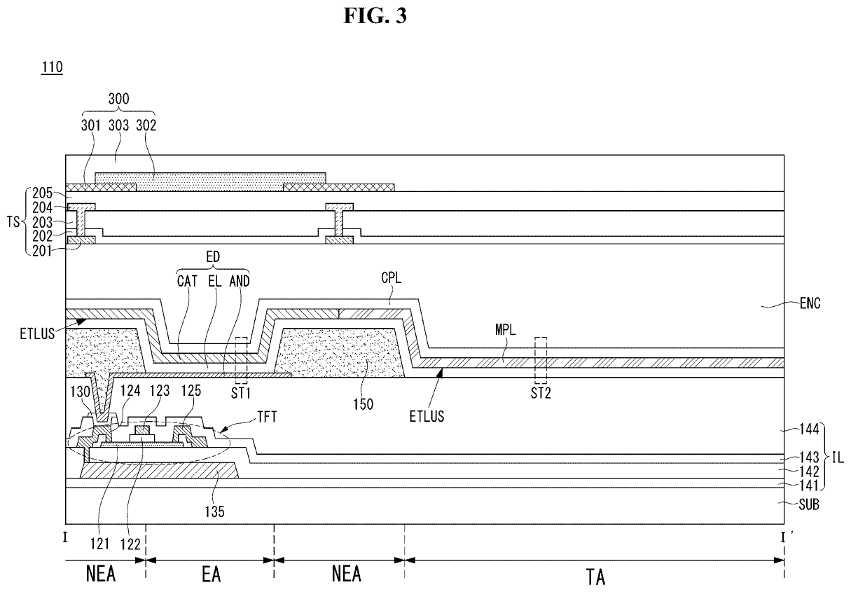

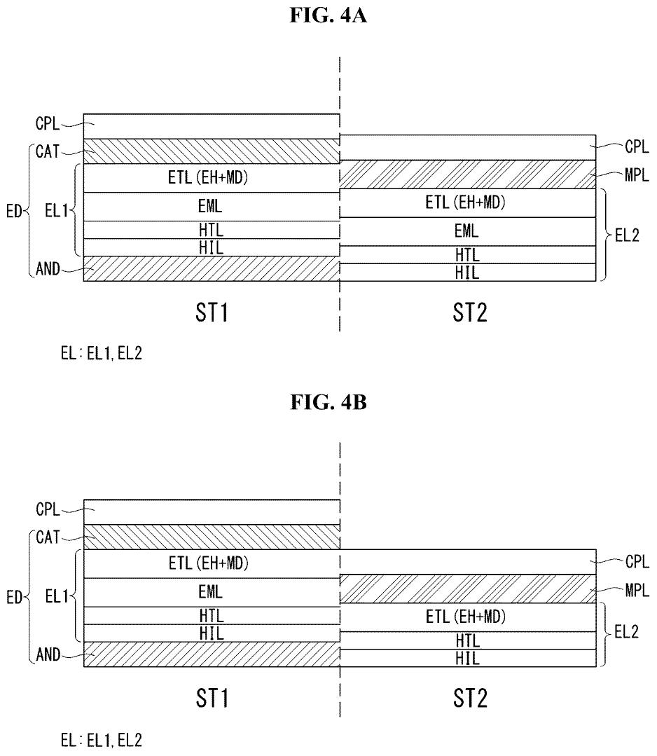

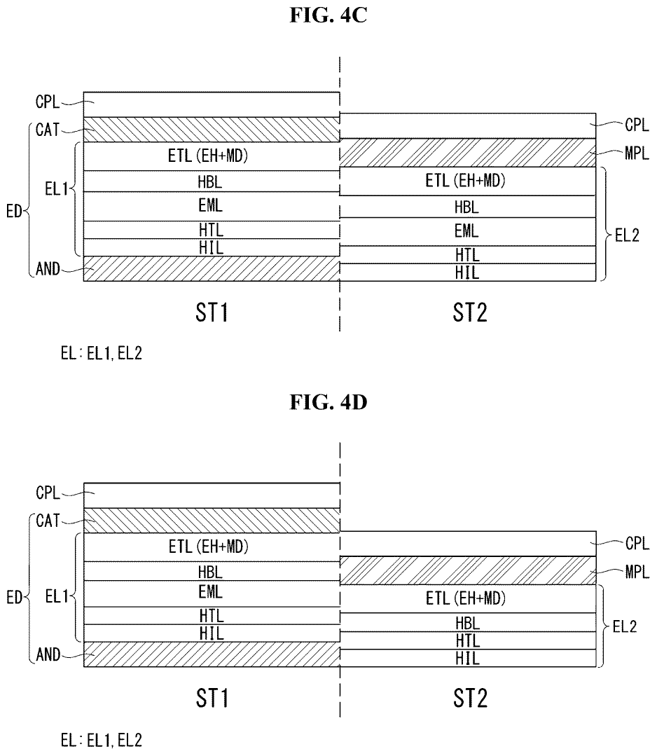

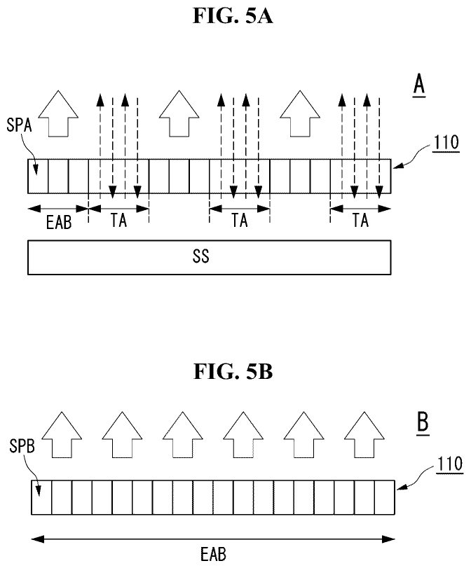

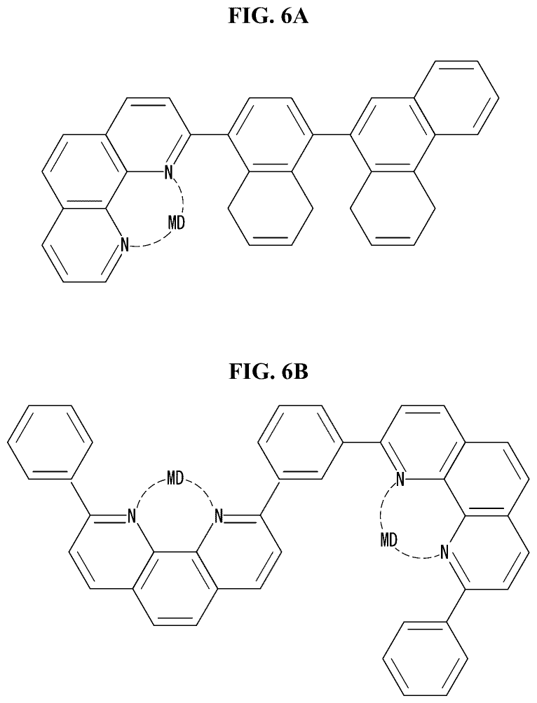

FIG. 1 is a plan view showing a display device according to an embodiment of the invention. FIG. 2 is an enlarged views showing areas A and B of FIG. 1. FIG. 3 is a cross-sectional view taken along line I-I′ of FIG. 2. FIGS. 4A to 4D are cross-sectional views respectively showing ST1 and ST2 of FIG. 3 according to embodiments of the invention. FIGS. 5A and 5B are schematic cross-sectional views of areas A and B, respectively, of FIG. 1, related to light propagation. FIGS. 6A and 6B are drawings showing the state in which a metal dopant is bound to an organic host in the uppermost layer of an intermediate layer.

Referring to FIG. 1, the display device 100 according to the embodiment of the invention includes a display panel 110 including an active area AA and a non-active area NA, and a cover member 20 disposed outside the display panel 110.

The cover member 20 may be located at side and rear surfaces of the display panel 110, and at least on a part of the top of the display panel 110 to protect the display panel 110 from external impact. An edge portion of the cover member 20 may have a curvature portion or curved portion bent in a direction toward a rear of the display device 100 (−Z axis direction). This allows the cover member 20 to be located so as to cover not only the rear surface of the display panel 110 but also the top and the side surface of the display panel 110, thereby protecting the display panel 110 from external impact in a plurality of directions.

The active area AA of the display device 100 may be an area that displays images, and the area other than the active area AA may be referred to as the non-active area NA. The active area AA and the non-active area NA of the display device 100 may be applied identically to the display panel 110. The active area AA is also referred to as a “display area”, and the non-active area NA is also referred to a “non-display area”.

The display device 100 of FIG. 1 is shown as an example having a planar, roughly rectangular shape elongated in a first direction (a Y-axis direction) with rounded corners. However, the display device according to the inventive concepts are not limited to the planar shape. Each corner of the display device 100 may also have an angular shape where a side in the first direction (the Y-axis direction) and a side in a second direction (an X-axis direction) are perpendicularly connected to each other. The display device 100 may also have a polygonal shape other than a rectangular shape.

The display device 100 includes a substrate SUB (see FIG. 3 and subsequent figures) having both an active area AA and a non-active area NA. A plurality of data lines DL extending in the first direction (e.g., the Y-axis direction) and a plurality of scan lines SL extending in the second direction (e.g., the X-axis direction) intersecting the first direction may be disposed in the active area AA on the substrate. The active area AA may include a plurality of subpixels SP, each of which may be connected to the data line DL and the scan line SL.

The active area AA may be divided into a sensor area A where a sensor member is disposed and a non-sensor area B where no sensor member is disposed.

In FIG. 1, the area where the sensor member is disposed is denoted by A1 and A2. FIG. 1 shows an example where two sensor members are provided in the sensor area A. However, embodiments of the invention are not limited thereto. The display device 100 may include one or more sensor members.

The sensor member may include, for example, a camera, an infrared camera, an infrared sensor, an ambient light sensor, and a fingerprint sensor. The sensor member may be disposed as a separate structure under the display panel 110 and may be protected by the cover member 20. In some cases, the sensor member may include a part inserted into the display panel 110.

The sensor member may not be visible from the top of the display panel 110 due to array configurations, e.g., shielding components such as the scan lines, the data lines, a light emission control line, a thin film transistor TFT, a light-shielding layer, and a bank, which are included on the substrate SUB of the display panel 110.

Referring to FIGS. 3 and 5A, the sensor member SS is located under the display panel 110, specifically lower than a light emitting element ED included in the display panel 110.

For example, as shown in FIG. 5A, the sensor member SS, such as an infrared sensor, an ambient light sensor, or a fingerprint sensor, receives and senses light generated above the display panel 110. Alternatively, the sensor member SS including an imaging sensor, such as a camera or an infrared camera, receives external light and, based on the received light, generates an additional image via the emission part, enabling the display panel to output the additional image to the outside. In the display device 100 according to the embodiment of the invention, the display panel 110 disposed on the sensor member SS includes a transmission part TA with secured transmittance to enhance the sensing sensitivity of the sensor member, as shown in FIGS. 2 and 3. Referring to FIG. 2, for example, the display panel 110 overlapping the sensor member SS may further include a transmission part TA provided in at least the sensor area A in addition to emission parts EA1, EA2, and EA3. Since the sensor area A has both the emission parts EA1, EA2, and EA3 and the transmission part TA, both image display and sensing of external light are possible.

As shown in FIG. 2, a pixel unit PU including first to third emission parts EA1, EA2, and EA3 that emit light of different colors is provided in the non-sensor area B with a uniform disposition density. As shown in FIG. 5B, second subpixels SPB included in the pixel unit PU are regularly disposed in the non-sensor area B, whereby an image may be displayed upward from the second subpixels SPB.

The pixel unit PU includes, for example, a first emission part EA1 and a third emission part EA3 each having a rhombus shape and a second emission part EA2 disposed diagonally relative to the first emission part EA1 or the third emission part EA3. The second emission part EA2 may have a long oval shape in a diagonal direction. The second emission part EA2 may be disposed, for example, between the first emission part EA1 and the third emission part EA3 in the diagonal direction from the top-left to the bottom-right and in the diagonal direction from the bottom-right to the top-left, respectively. The shapes of the first to third emission parts EA1, EA2, and EA3 are shown as an example and may be changed to other polygonal or oval shapes.

In the shown example, the pixel unit PU includes one first emission part EA1, two second emission parts EA2, and one third emission part EA3. This compensates for the difference in viewing angle characteristics of the second emission part EA2, which is elongated on one side relative to the first and third emission parts EA1 and EA3.

The area of the first to third emission parts EA1, EA2, and EA3 may vary in size according to the required luminance of each color for the display device 100 to display white. In the shown example, the third emission part EA3 is the largest and the first emission part EA1 is the smallest, but this may be changed depending on the luminance characteristics or color temperature characteristics that the display device 100 intends to display.

For example, the first emission part EA1, the second emission part EA2, and the third emission part EA3 may be a red emission part, a green emission part, and a blue emission part, respectively.

In an emission part disposition area EAB of the sensor area A and the non-sensor area B, the area where the first to third emission parts EA1, EA2, and EA3 are not disposed may be a non-emission part NEA. The emission part disposition area EAB of the sensor area A and the non-sensor area B may include subpixels SPA and SPB. Each of the subpixels may include emission parts EA (EA1, EA2, and EA3) and a non-emission part NEA around the emission parts EA (EA1, EA2, and EA3).

Subpixels disposed in the emission part disposition area EAB of the sensor area A may be referred to as first subpixels SPA, while subpixels disposed in the non-sensor area B may be referred to as second subpixels SPB. The first subpixels SPA and the second subpixels SPB may have different disposition densities. The disposition density of the first subpixels SPA including the emission parts EA1, EA2, and EA3 in the sensor area A is lower than the disposition density of the second subpixels SPB in the non-sensor area B, allowing the sensor area A to have a lower resolution than the non-sensor area B.

As shown in FIG. 2B, the non-sensor area B, which does not overlap the sensor member, may include pixel units PU including the first to third emission parts EA1, EA2, and EA3 at a regular disposition density. In contrast, as shown in FIG. 5A, the sensor area A overlapping the sensor member may include the transmission part TA in addition to the emission part disposition area EAB where the pixel units PU are disposed, to ensure transmission.

The sensor area A, by including the emission part disposition area EAB, enables image display even in the area overlapping the sensor member. Therefore, display is implemented in both the sensor area A and the non-sensor area B across the entire active area AA, enabling full-screen image display.

A light emitting element ED (FIG. 3) is disposed in each of the emission parts EA (EA1, EA2, and EA3). The light emitting element ED includes an anode AND, an intermediate layer EL, and a cathode CAT. The anode AND and the cathode CAT are not disposed in the transmission part TA, which is therefore unaffected by the light-shielding or reflective properties of the electrodes.

The anode AND may be disposed so as to correspond to each of the emission parts EA (EA1, EA2, and EA3). The anode AND may be disposed in each of the emission parts EA1, EA2, and EA3 with an area greater than the area of each of the emission parts EA1, EA2, and EA3.

Referring to FIG. 3, the emission parts EA1, EA2, and EA3 may be defined by a bank 150. An open area of the bank 150 in the emission part disposition area EAB of the sensor area A and the non-sensor area B may be defined as the emission parts EA1, EA2, and EA3.

The intermediate layer EL may be commonly provided over the emission parts EA, the non-emission part NEA between the emission parts EA, and the transmission part TA, as shown in FIG. 3. As shown in FIG. 4A, the intermediate layer EL may include a hole injection layer HIL, a hole transport layer HTL, a light emitting layer EML, and an electron transport layer ETL. Here, the electron transport layer ETL may be the uppermost layer of the intermediate layer.

In FIG. 4A, the configuration of the light emitting element ED located in the emission part EA is shown as ST1, and the configuration located in the transmission part TA so as to correspond to the light emitting element ED is shown as ST2. In the display device according to the embodiment of the invention, the emission part EA and the transmission part TA may include the same intermediate layers EL1 or EL2, as shown in FIG. 4A. That is, the transmission part TA may also include a hole injection layer HIL, a hole transport layer HTL, a light emitting layer EML, and an electron transport layer ETL. In this case, a lower surface of the electron transport layer ETL may commonly contact the light emitting layer EML in both the emission part EA and the transmission part TA.

In another embodiment of the display device according to the invention, as shown in FIG. 4B, the light emitting layer EML may be disposed so as to correspond to each of the emission parts EA (EA1, EA2, and EA3) using a separate FMM mask, and the light emitting layer EML may not be provided in the transmission part TA. That is, the intermediate layer EL1 of the emission part EA and the intermediate layer EL2 of the transmission part TA may differ in whether the light emitting layer EML is included. In this case, the lower surface of the electron transport layer ETL in the transmission part TA may contact the hole transport layer HTL, while the lower surface of the electron transport layer ETL in the emission part EA may contact the light emitting layer EML.

As shown in FIG. 4C, the intermediate layer EL (EL1 or EL2) may further include a hole blocking layer HBL between the light emitting layer EML and the electron transport layer ETL to prevent holes from being transferred from the light emitting layer EML to the electron transport layer ETL. The hole blocking layer HBL may be made of an organic material different from an organic host included in the electron transport layer ETL and may have a HOMO energy level lower than the HOMO energy level of the electron transport layer ETL to prevent migration of holes to an electron blocking layer adjacent thereto. Here, the lower surface of the electron transport layer ETL may contact the hole blocking layer HBL. Alternatively, the intermediate layer EL (EL1 or EL2) may further include a hole blocking layer HBL commonly in the emission part EA and in the transmission part TA, as shown in FIG. 4D. As shown in FIG. 4D, the hole blocking layer HBL is provided between the light emitting layer EML and the electron transport layer ETL to prevent holes from being transferred from the light emitting layer EML to the electron transport layer ETL in the emission part EA, and a low surface of the hole blocking layer HBL may be in contact with the hole transport layer HTL in the transmission part TA.

The intermediate layer EL1 or EL2 may include a configuration common to both the emission part EA and the transmission part TA. FIG. 4A shows a hole injection layer HIL, a hole transport layer HTL, a light emitting layer EML, and an electron transport layer ETL as the configuration of the common layer, and FIG. 4B shows a hole injection layer HIL, a hole transport layer HTL, and an electron transport layer ETL as the configuration of the common layer. The intermediate layer EL1 of the emission part may further include a functional layer for each subpixel emission part.

As the uppermost layer of the intermediate layers EL1 or EL2, the electron transport layer ETL may include both an electron-transportable organic host EH and a metal dopant MD, thereby serving both the function of the electron transport layer and the function of the electron injection layer.

FIGS. 2A and 2B show the cathode CAT disposed in the sensor area A and non-sensor area B. For example, the cathode CAT may be disposed over the entirety of the non-sensor area B, and the cathode CAT may be disposed in the sensor area A excluding the transmission part TA.

In the display device according to the embodiment of the invention, the transmission part TA in the sensor area A is provided with a pattern definition layer MPL, wherein a material for forming the cathode CAT may be repelled during formation of the cathode CAT due to the low surface energy of the pattern definition layer MPL, allowing the cathode CAT to be formed in the area excluding the pattern definition layer MPL.

The pattern definition layer MPL may be disposed on the intermediate layer EL. After the pattern definition layer MPL is provided on the intermediate layer EL before formation of the cathode CAT, a cathode formation material may be deposited in the area excluding the pattern definition layer MPL, whereby a cathode CAT having a transmission part TA may be provided in an area corresponding to the pattern definition layer MPL through an open mask that opens the entire active area AA without using a separate fine metal mask (FMM). Here, the pattern definition layer MPL has a deposition suppression effect on the cathode material due to the surface properties of the material.

The cathode CAT may overlap all emission parts EA (EA1, EA2, and EA3) provided in the entire active area AA.

In addition, the cathode CAT is disposed not only on each emission part but also on the non-emission part NEA of the first subpixels SPA disposed in the emission part disposition area EAB of the sensor area A and the second subpixels SPB disposed in the non-sensor area B. The cathode CAT in the emission part disposition area EAB of the sensor area A and the cathode CAT in the non-sensor area B may be integrally connected to each other. The cathode CAT may have a shape with a hole corresponding to the transmission part TA. Therefore, as shown in FIG. 2A, the pattern definition layer MPL may be disposed in the sensor area A as an island shape, and the cathode CAT may be disposed as an integral shape across the entire active area AA, excluding the area where the pattern definition layer MPL is disposed.

The pattern definition layer MPL has low electrical affinity and low surface energy for a conductive material, such as a metal, whereby the pattern definition layer has the function to suppress the deposition of a metal onto the pattern definition layer MPL during the deposition of the metal material forming the cathode CAT. Accordingly, after forming the cathode CAT using the pattern definition layer MPL, the final section may exhibit a configuration where side surfaces of the pattern definition layer MPL and the cathode CAT are adjacent to each other, as shown in FIG. 3.

For example, the pattern definition layer MPL may include a polycyclic aromatic compound that is partially substituted with at least one atom of N (nitrogen), S (sulfur), O (oxygen), P (phosphorus), and Al (aluminum) on a part of an aromatic ring as an organic material. In addition, the polycyclic aromatic compound may include an organic molecule including a core moiety and at least one terminal moiety bonded to the core moiety. For example, the pattern definition layer MPL may include any one of TAZ (3-(4-biphenyl)-4-phenyl-5-tert-butylphenyl-1,2,4-triazole), BAlq (bis(8-hydroxy-2-methylquinoline)-(4-phenylphenoxy)aluminum), Liq(8-quinolinolato lithium), 2-(4-(9,10-di(naphthalen-2-yl)anthracen-2-yl)phenyl)-1-phenyl-1H-benzo[d]imidazole, and N-([1,1′-biphenyl]-4-yl)-9,9-dimethyl-N-(4-(9-phenyl-9H-carbazol-3-yl)phenyl)-9H-fluoren-2-amine.

However, the display device according to the inventive concepts is not limited to the material of the pattern definition layer MPL described above. The material of the pattern definition layer MPL may be replaced with other organic materials as long as the material possesses transparency and has lower surface energy and lower electrical affinity than the uppermost layer of the intermediate layer EL. The area where the pattern definition layer MPL is disposed repels the deposition of a metal material for cathode formation due to the low surface energy and low electron affinity thereof, preventing the cathode metal material from being deposited on the pattern definition layer MPL.

Defining the cathode CAT disposition area using the pattern definition layer MPL is not merely significant for reducing a mask required for CAT deposition. The cathode CAT is made of a metal material capable of deposition at high temperatures. When patterned through the fine metal mask (FMM), deformation of the FMM mask may occur during the high-temperature deposition process, potentially leading to poor disposition of the cathode in the transmission part. In the display device according to the inventive concepts, the area of the transmission part may be first defined using a pattern definition layer MPL made of an organic material that can be deposited at lower temperatures than a metal, and the cathode may be disposed outside the pattern definition layer MPL due to the repulsive force of the pattern definition layer MPL, which prevents the use of the FMM susceptible to deformation during high-temperature deposition.

In the display device according to the inventive concepts, the pattern definition layer MPL and the cathode CAT may each contact the uppermost layer of the same intermediate layer EL. The uppermost layer of the intermediate layer EL may be an electron transport layer ETL. Therefore, as shown in FIG. 3, lower surfaces of the pattern definition layer MPL and the cathode CAT may contact an upper surface ETLUS of the electron transport layer ETL.

The display device according to the inventive concepts does not have an electron injection layer constituted by a mixture of inorganic materials on the uppermost layer of the intermediate layer EL, thereby preventing the inorganic material included in the electron injection layer from altering the surface energy properties of the pattern definition layer MPL.

In the display device according to the inventive concepts, the uppermost layer of the intermediate layer EL includes an electron-transportable organic host EH and a metal dopant MD. Here, the electron transport layer ETL, which is the uppermost layer of the intermediate layer EL, includes an electron-transportable organic host EH as the main material and additionally includes a small amount of a metal dopant MD.

The metal dopant MD may be included in the electron transport layer ETL, which is the uppermost layer of the intermediate layer EL, in a range of 0.001 wt % to 10 wt %, and the organic host EH may be included in a range of 90 wt % to 99.999 wt %. For example, when the intermediate layer EL includes a plurality of light emitting stacks, each having an electron transport layer, the electron transport layer ETL, which is the uppermost layer of the intermediate layer EL, may differ in material from an electron transport layer located in another light emitting stack. In addition, the electron transport layer of the other light emitting stack, excluding the electron transport layer ETL, which is the uppermost layer of the intermediate layer EL, may not have a metal dopant. A charge generation layer may be provided between the plurality of light emitting stacks of the intermediate layer EL, and the charge generation layer may include, for example, an n-type charge generation layer and a p-type charge generation layer. The organic host in the uppermost layer of the intermediate layer according to the embodiment of the invention may include the same material as the n-type charge generation layer.

The electron transport layer ETL, which is the uppermost layer of the intermediate layer EL, may include a metal dopant MD to provide an electron injection function.

The LUMO energy level of the organic host EH is −3.5 eV to −2.0 eV, and the absolute value of the LUMO energy level of the organic host EH may be equal to or similar to the work function of the metal or metal alloy forming the cathode CAT. The LUMO energy level of the organic host EH is within a range that facilitates electron injection from the cathode CAT. If the LUMO value of the organic host EH is lower than −3.5 eV, electron injection becomes difficult at the interface with the cathode CAT, leading to an increase in drive voltage. In addition, if the LUMO value of the organic host EH is higher than −2.0 eV, this is a very shallow value close to the vacuum level, making it difficult to manufacture the same using an organic compound and to maintain stable characteristics thereof.

In the electron transport layer ETL, which is the uppermost layer of the intermediate layer EL, the metal dopant MD may be bound to the organic host EH to prevent diffusion thereof into layers other than the electron transport layer ETL.

The inclusion of the metal dopant MD in the electron transport layer ETL may adjust the LUMO energy level of the ETL slightly above the LUMO energy level of the organic host EH. The LUMO energy level of the electron transport layer ETL may be −3.3 eV to −2.0 eV.

Other physical characteristics of the organic host EH are as follows.

The HOMO energy level of the organic host EH may have a value of about −7.0 eV to −5.5 eV. The organic host EH may have an energy bandgap of about 2.0 eV to 4.5 eV, enabling stable characteristics.

The organic host EH may have a triplet energy level T1 of about 2 eV to 3 eV. The organic host EH may contact the light emitting layer EML or the hole blocking layer HBL on a second surface, which is opposite a first surface where the electron transport layer ETL contacts the cathode CAT and the pattern definition layer MPL, and may have a triplet energy level similar to or higher than the triplet energy level of the light emitting layer EML or the hole blocking layer HBL, facilitating energy transfer toward a host or a luminescent dopant provided in the light emitting layer EML.

The refractive index of the organic host EH is about 1.5 to 2.5. The refractive index of the organic host EH may be similar to the refractive index of the intermediate layer EL.

The organic host EH in the electron transport layer ETL, which is the uppermost layer of the intermediate layer EL, includes an organic compound that can be bound with a metal dopant MD. For example, the organic host EH may contain phenanthrolinyl or phenanthrollinylene. Two nitrogen atoms included in phenanthrolinyl or phenanthrollinylene have electron-donating properties, enabling the electron transport layer ETL to have high electron mobility, and bind the metal dopant MD, preventing diffusion of the metal dopant MD into surrounding layers.

In the electron transport layer ETL, the organic host EH may include another organic pendant on one side of phenanthrolinyl, or may have phenanthrollinylene as the core with an organic linker and/or an organic pendant added on both sides, allowing adjustment of the HOMO and LUMO energy levels.

For example, the metal dopant MD included in the uppermost layer of the intermediate layer may be an alkali metal or an alkaline earth metal having a work function of about 3.0 eV or less. For example, the metal dopant MD may include at least one of lithium (Li), cesium (Cs), calcium (Ca), barium (Ba), sodium (Na), potassium (K), and rubidium (Rb).

In the display device according to the inventive concepts, in a structure where the area of the cathode CAT is defined by the pattern definition layer MPL, the material of the uppermost layer of the intermediate layer abutting the lower sides of the pattern definition layer MPL and the cathode CAT is primarily an electron-transportable organic host EH, preventing changes in the surface energy of the pattern definition layer MPL and thereby preventing a residual layer of the cathode CAT on the pattern definition layer MPL. In contrast, for example, in the structure of the display device in which the electron injection layer is the uppermost layer of the intermediate layer, the surface energy of a metal fluoride or a doped metal included in the electron injection layer is high, the surface energy of the pattern definition layer MPL provided on the electron injection layer may be increased, which may cause a residual layer of the cathode material on the pattern definition layer MPL during cathode material deposition.

In the display device according to the inventive concepts, the electron injection layer that affects the surface energy of the pattern definition layer MPL is omitted, and the uppermost layer of the intermediate layer is constituted primarily of an organic host EH that exhibits excellent interface compatibility with the cathode CAT, excellent electron transport properties, and binding characteristics that prevent diffusion of the included metal dopant MD.

FIG. 6A shows an example where phenanthrolinyl is included as the organic host EH, wherein a pendant connector including naphthalene and phenanthrene at one side of phenanthrolinyl is included. When the metal dopant MD is included in the uppermost layer of the intermediate layer, the metal dopant is bound so as to be adjacent to symmetrically located nitrogen atoms N of phenanthrolinyl forming the organic host EH, whereby diffusion of the metal dopant to the pattern definition layer, the underlying light emitting layer, or the hole blocking layer may be prevented. Here, the migration of the metal dopant is suppressed not through direct covalent or ionic bonds with phenanthrolinyl but through electrostatic attraction between the nitrogen atom and the metal dopant.

FIG. 6B shows another example including phenanthrollinylene as the organic host EH, wherein phenanthrollinylene is doubly constituted as the core, phenyl is included as a linker therebetween, and phenyl is included as a pendant. When the metal dopant is included in the uppermost layer of the intermediate layer, the metal dopant is bound so as to be adjacent to symmetrically located nitrogen atoms of phenanthrollinylene forming the organic host, whereby diffusion of the metal dopant to the pattern definition layer, the underlying light emitting layer, or the hole locking layer may be prevented.

In the area excluding the pattern definition layer MPL, the cathode CAT in contact with the uppermost layer of the intermediate layer may include a metal exhibiting excellent interfacial compatibility with the organic host EH included in the uppermost layer of the intermediate layer. To this end, the cathode CAT may be a metal or a metal alloy including at least one of silver (Ag), gold (Au), platinum (Pt), palladium (Pd), copper (Cu), magnesium (Mg), aluminum (Al), titanium (Ti), tungsten (W), and molybdenum (Mo).

The work function of the cathode CAT is 4.0 eV or less. Since electrons are injected from the cathode CAT into the uppermost layer of the intermediate layer, i.e., the electron transport layer ETL, the work function of the cathode may be equal to the absolute value of the LUMO energy level of the organic host EH included in the uppermost layer of the intermediate layer or may have a difference of 1 eV or less such that the energy barrier is not high. In addition, the work function of the cathode CAT may be the same as or differ by 1 eV or less from the work function of the metal dopant MD included in the uppermost layer of the intermediate layer.

The configurations of the emission part EA and the transmission part of the display device according to the inventive concepts will be described for comparison with reference to FIGS. 3 and 4A.

Referring to FIGS. 1 to 3, a substrate SUB of the display device 100 includes an active area AA including a first area and a second area and a non-active area NA outside the active area AA. In the above description, the non-sensor area B where the emission parts EA (EA1, EA2, and EA3) are regularly disposed may be the first area, and the sensor area A having both the emission part disposition area EAB and the transmission part TA may be the second area.

For example, the substrate SUB may include a thin glass or a flexible film. In some cases, the substrate SUB may include first and second organic layers overlapping each other with an inorganic interlayer insulating layer interposed therebetween. Here, the inorganic interlayer insulating layer may function to block migration of moisture or impurities between the first and second organic layers. The inorganic interlayer insulating layer is formed on the first organic layer and may include a part-patterned configuration. The inorganic interlayer insulating layer may include at least one of a silicon nitride layer, a silicon oxide layer, and a silicon nitride-oxide layer. Each of the first and second organic layers may include, for example, a flexible layer, such as polyethylene terephthalate (PET) or polyimide. In addition to polyimide or PET, the first and second organic layers may include different organic layers.

The substrate SUB supports and protects the components of the display device disposed thereon.

A plurality of insulating layers IL (141, 142, 143, and 144) may be disposed in the emission part EA and the transmission part TA of the substrate SUB.

The plurality of insulating layers IL may include, for example, a first insulating layer 141, a second insulating layer 142, a third insulating layer 143, and a fourth insulating layer 144. Each of the first to fourth insulating layers 141, 142, 143, and 144 may be independently formed as a single layer or a plurality of layers.

A thin film transistor TFT may be provided on the substrate SUB so as to be electrically connected to the light emitting element ED disposed in the emission part EA.

The thin film transistor TFT may be disposed on the first insulating layer 141 and the second insulating layer 142, which function as buffer layers.

The first insulating layer 141 prevents impurities from being introduced from the substrate SUB, and may level a formation surface during the formation of a light-shielding layer 135.

The thin film transistor TFT includes an active layer 121, a gate electrode 123 overlapping the active layer 121 with a gate insulating layer 122 interposed therebetween, and a first source-drain electrode 124 and a second source-drain electrode 125 connected to each other while being spaced apart from the active layer 121.

The active layer 121 may include, for example, at least one of an oxide semiconductor, amorphous silicon, and crystalline silicon. When the active layer 121 includes an oxide semiconductor, the oxide semiconductor may include, for example, at least one of indium, gallium, zinc, and tungsten.

Under the active layer 121, a light-shielding layer 135 with a light-shielding function may be further included to prevent the thin film transistor TFT from being affected by light entering from the substrate SUB.

The light-shielding layer 135 may be made of a metal line. The light-shielding layer 135 may be connected to the first source-drain electrode 124 to prevent the influence of parasitic capacitance caused by adjacent conductive structures.

A second insulating layer 142 may be disposed between the light-shielding layer 135 and the active layer 121. The second insulating layer 142 may planarize a surface on which the active layer 121 is disposed.

The gate insulating layer 122 included in the thin layer transistor TFT may insulate the gate electrode 123 and the active layer 121 from each other.

The third insulating layer 143 is located above the thin film transistor TFT and serves to protect the thin film transistor TFT.

The first insulating layer 141 may include at least one of silicon oxide (SiOₓ), silicon nitride (SiNₓ), and silicon oxide-nitride (SiOₓN_{y}), or may include a multilayer layer formed by stacking the inorganic layers described by way of example.

The first source-drain electrode 124 of the thin film transistor TFT may be electrically connected to the anode AND located thereunder via a connection electrode 130 interposed between the first source-drain electrode 124 and the anode AND.

The fourth insulating layer 144 having a planarization function is located above the connection electrode 130 to protect the underlying structure and to planarize the formation surface of the light emitting element. The fourth insulating layer 144 has a contact hole configured to expose at least a part of the connection electrode 130, and the anode AND located above the fourth insulating layer 144 is connected to the connection electrode 130 via the contact hole.

For example, each of the light-shielding layer 135, the gate electrode 123, the first and second source-drain electrodes 124 and 125, and the connection electrode 130 may be made of a conductive metal material. Specifically, the conductive metal material may include at least one of an aluminum-based metal, such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

Each of the first to third insulating layers 141, 142, and 143 may include an inorganic insulating layer, such as silicon oxide (SiOₓ) or silicon nitride (SiNₓ), or a multilayer layer thereof.

The fourth insulating layer 144 may be made of an organic insulating material. In some cases, the fourth insulating layer 144 may have a plurality of layers. The fourth insulating layer 144 may include at least one of silver, an acrylic resin, a phenolic resin, a polyimide resin, an unsaturated polyester resin, a polyamide resin, benzocyclobutene, a polyphenylene resin, and a polyphenylene sulfide resin.

The fourth insulating layer 144 may be thicker than each of the first to third insulating layers 141, 142, and 143, and may include a material that facilitates surface planarization.

In some cases, the connection electrode 130 may be omitted. When the connection electrode 130 is omitted, the first source-drain electrode 124 may be directly connected to the anode AND of the light emitting element ED.

The light emitting element ED includes a stack of an anode AND, an intermediate layer EL, and a cathode CAT. The anode AND may be provided independently for each subpixel SP and may be separated from adjacent subpixels. The anode AND overlaps the entire area of the emission part EA and extends to the outside of the emission part EA, whereby the edge of the anode AND may overlap the bank 150 defining the emission part EA.

As an example, the anode AND may include a highly reflective metal material or may include a transparent electrode. When the anode AND is formed as a single layer of a transparent conductive layer, light from the light emitting element ED may be emitted through the anode AND. In this case, at least the thin film transistor TFT may be disposed so as not to overlap the emission part EA. If the anode AND includes a reflective electrode, light may be emitted through the cathode CAT opposite the anode AND.

The anode AND may include, for example, a reflective electrode and may function to shield light incident onto the thin film transistor TFT disposed under the light emitting element ED. The anode AND may have, for example, a stack structure of a first transparent electrode, a reflective electrode, and a second transparent electrode. The second transparent electrode, which is the uppermost electrode of the anode AND, may be a dielectric, which may lower a barrier for hole injection at the interface with the intermediate layer EL. Here, each of the first and second transparent electrodes may be a transparent oxide electrode such as ITO (indium tin oxide) or IZO (indium zinc oxide). The reflective electrode may include silver (Ag), a silver alloy, such as APC (Ag—Pd—Cu), aluminum (Al), or an aluminum alloy.

The cathode CAT may include a thin reflective-transmissive electrode to enable light transmission. The cathode CAT including the reflective-transmissive electrode may have a thickness of, for example, 30 nm or less, such as 4 nm to 20 nm. The reflective-transmissive electrode may be a metal or a metal alloy including at least one of, for example, silver (Ag), gold (Au), platinum (Pt), palladium (Pd), copper (Cu), magnesium (Mg), aluminum (Al), titanium (Ti), tungsten (W), and molybdenum (Mo). The work function of the cathode including the above metal may be equal to the absolute value of the LUMO energy level of the organic host EH included in the uppermost layer of the intermediate layer or may have a difference of 1 eV or less, and the work function of the metal dopant MD may have a difference of 1 eV or less. The metal dopant MD may have a work function similar to that of the cathode CAT in electron injection, thereby lowering the electron injection barrier.

The bank 150 may be provided so as to cover the edge of the anode AND, and an opening in the bank 150 on the anode AND may be defined as an emission part. The bank 150 may include a light-shielding organic insulating material and/or a transparent organic insulating material to maintain a certain vertical thickness. The bank 150 may have a vertical thickness of, for example, 1 μm to 5 μm.

In order to prevent a deposition mask from contacting the bank 150 during the deposition process of the intermediate layer EL on at least a part of the bank 150, a spacer may be further provided. The spacer may be made of an organic insulating material identical to or different from the material of the bank 150.

As shown in FIGS. 3 and 4A or 4B, the electron transport layer ETL of the intermediate layer EL directly contacts the cathode CAT and the pattern definition layer MPL. In the display device according to the embodiment of the invention, the electron injection layer may be omitted, thereby preventing the electron injection layer from changing the surface energy characteristics of the pattern definition layer MPL, preventing the occurrence of a residual layer of the cathode, and preventing the components of the electron injection layer from affecting transmittance.

The intermediate layer EL may be disposed on the bank 150 of the non-emission part NEA, the anode AND of the emission part EA, and the fourth insulating layer 144 of the transmission part TA.

The pattern definition layer MPL may be disposed first on the intermediate layer EL so as to correspond to the transmission part TA, and the cathode CAT may be disposed over the entirety of the active area AA where the pattern definition layer MPL is not disposed.

A capping layer CPL configured to enhance light emission efficiency and protect the upper structure of the light emitting element ED may be provided on the cathode CAT and pattern definition layer MPL. The capping layer CPL may be provided commonly at the emission part EA and the transmission part TA.

An encapsulation layer ENC configured to protect the components, such as the light emitting element ED, on the substrate SUB is provided on the capping layer CPL. The encapsulation layer ENC may include at least one inorganic encapsulation layer and at least one organic encapsulation layer. The inorganic encapsulation layer may prevent the propagation of external air or moisture to the light emitting element ED side. The organic encapsulation layer may uniformly cover particles generated during the process from above and protect the lower components. Furthermore, the organic encapsulation layer functions to mitigate bending or folding stresses on the display device.

In addition, an upper surface of the encapsulation layer ENC is flat, allowing the omission of a separate protective layer and enabling direct use thereof as a formation surface for a touch sensor TS and/or a color filter array 300. FIG. 3 shows an example in which the touch sensor TS is disposed on the encapsulation layer ENC.

The touch sensor TS may include, for example, a bridge layer 201, a touch buffer layer 202 provided on the bridge layer, a touch intermediate insulating layer 203, and a sensor electrode 204 connected to the bridge layer 201 through the touch intermediate insulating layer 203 and the touch buffer layer 202.

A touch protective layer 205 may be further provided on the sensor electrode 204 of the touch sensor TS.

Each of the bridge layer 201 and the sensor electrode 204 of the touch sensor TS may include, for example, a metal layer including at least one of Ti, Al, Mo, MoTi, Cu, Ta, Cr, and ITO (indium tin oxide), which are highly conductive. In some cases, each of the bridge layer 201 and the sensor electrode 204 may be formed in a mesh pattern. For example, the mesh metal layer may be formed so as to have a stacked multilayer structure such as Ti/Al/Ti, MoTi/Cu/MoTi, or Ti/Al/Mo.

Each of the touch buffer layer 202, the touch intermediate insulating layer 203, and the touch protective layer 205 of the touch sensor TS may be made of an inorganic or organic insulating material capable of low-temperature deposition to prevent interference with the components under the encapsulation layer ENC. For example, each of the touch buffer layer, the touch intermediate insulating layer 203, and the touch protective layer 205 may independently include at least one of silicon nitride, silicon oxide, silicon nitride-oxide, polyacrylic, and polyamide.

The color filter array 300 may include a black matrix layer 301 configured to prevent visibility of the underlying structure, a color filter layer 302 corresponding to the emission part EA and configured to selectively transmit the wavelength of the color to be displayed for a predetermined subpixel, and a protective layer 303 provided on the black matrix layer 301 and the color filter layer 302 to protect the same from the outside.

The color filter array 300 may be further provided on the touch sensor TS. In some cases, the color filter array 300 may be omitted when the light emitting layer EML of each of the emission parts EA (EA1, EA2, and EA3) displays a predetermined color per subpixel.

In the transmission part TA, the anode AND and the cathode CAT, which are components of the light emitting element ED, may be omitted. As the upper structure, the bridge layer 201 and the sensor electrode 204 of the touch sensor TS, the black matrix layer 301, and the color filter layer 302 may all be omitted, thereby securing a higher transmittance for the transmission part TA.

In some cases, at least a part of the insulating layer IL and at least some of the touch buffer layer 202, the touch intermediate insulating layer 203, and the touch protective layer 205 included in the touch sensor TS may be omitted from the transmission part TA, thereby further improving the transmittance of the transmission part TA.

In the display device according to the inventive concepts, it is possible to define the formation position of the cathode using the pattern definition layer without using a separate fine metal mask.

In the display device according to the inventive concepts, it is possible to suppress changes in the surface energy of the pattern definition layer by using an electron-transportable organic host with a LUMO energy level within a certain range as the main material of the uppermost layer of the intermediate layer in contact with the pattern definition layer and the cathode. This may prevent the residual layer of the cathode from remaining on the pattern definition layer.

In the display device according to the inventive concepts, it is possible to effectively prevent changes in the characteristics of the pattern definition layer caused by the diffusion of the metal dopant by binding the metal dopant to the organic host to prevent the influence of metal dopant diffusion in the uppermost layer of the intermediate layer, thereby preventing the occurrence of the residual layer of the cathode in the area where the pattern definition layer is disposed and thus improving transmittance.

In the display device according to the inventive concepts, it is possible to improve the sensing sensitivity of the sensor member by providing the area where the cathode is not disposed in the area where the sensor member is disposed when applying the pattern definition layer to the area where the sensor member is disposed.

In the display device according to the inventive concepts, the visibility of a background image or an object is easy when the transmission part is uniformly disposed on the display device, whereby it is possible to implement a display device having improved transmittance.

In the display device according to the inventive concepts, it is possible to secure luminous characteristics without changes in luminance characteristics due to increases in drive voltage or current density, even in a structure not including an electron injection layer.

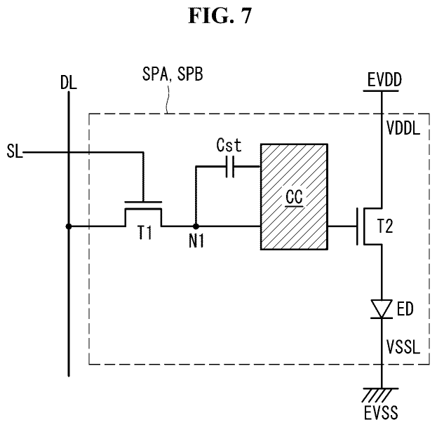

FIG. 7 is an equivalent circuit diagram of a subpixel provided in the active area of the display device according to an embodiment of the invention.

The first subpixels SPA in the sensor area A and the second subpixels SPB in the non-sensor area B may include circuits with identical functions, as shown in FIG. 7.

In both the sensor area A and the non-sensor area B, each subpixel SPA or SPB is disposed such that a plurality of data lines DL and a plurality of scan lines SL intersect. Each area partitioned by the intersection of the data lines DL and the scan lines SL may constitute one subpixel SPA or SPB. The subpixel SPA or SPB may include one emission part. The circuit configuration in the subpixel SPA or SPB is electrically connected to a light emitting element ED provided in each emission part, enabling the driving of the light emitting element.

In the embodiments of the invention, the emission parts EA (EA1, EA2, and EA3) are not necessarily limited to the areas partitioned by the intersections of the data lines DL and the scan lines SL. That is, at least a part of the emission part may intersect with the data lines DL and/or the scan lines SL.

The subpixel SPA or SPB is disposed, for example, as shown in FIG. 7, between a scan line SL and a data line DL intersecting with each other, and may include a first transistor T1, a second transistor T2, a storage capacitor Cst, a compensation circuit CC, and a light emitting element ED.

For example, the first transistor T1 may be a switching transistor, and the second transistor T2 may be a driving transistor.

Each of the first transistor T1 and the second transistor T2 may include an active layer, a gate electrode, and first and second source-drain electrodes. The active layer of at least one of the first and second transistors T1 and T2 may include at least one of amorphous silicon, crystalline silicon, and an oxide semiconductor. For example, the oxide semiconductor may include an oxide semiconductor material such as IGZO (indium-gallium-zinc-oxide).

The first transistor T1 is electrically connected to the data line DL and is electrically connected to a first node N1. The gate electrode of the first transistor T1 is electrically connected to the scan line SL. The first transistor T1 transmits a data signal supplied via the data line DL to the first node N1 in response to a scan signal supplied via the scan line SL.

The storage capacitor Cst is electrically connected to the first node N1 to charge the voltage applied to the first node N1.

The second transistor T2 is supplied with a high-potential drive voltage EVDD and is electrically connected to the anode of the light emitting element ED. The thin film transistor shown in FIG. 3 is an example and may function as the second transistor T2 of FIG. 7.

The second transistor T2 may control the amount of drive current flowing in the light emitting element ED in response to the voltage applied to the gate electrode. The high-potential drive voltage EVDD may be connected to the second transistor T2 via a first power voltage line VDDL.

The light emitting element ED outputs light corresponding to the drive current supplied from the second transistor T2. The light emitting element ED may output light corresponding to one of red, green, blue, and white colors.

The cathode may be connected to a second power voltage line VSSL that supplies a low-potential drive voltage EVSS. The second power voltage line VSSL may be connected to the cathode. The second power voltage line VSSL may be provided in the non-active area NA and/or the active area AA. Each subpixel SPA or SPB may receive the low-potential drive voltage EVSS to uniformly set the potential of subpixel-specific cathodes. The low-potential drive voltage EVSS may be a ground voltage or a voltage lower than the high-potential voltage EVDD applied via the first power voltage line VDDL.

The compensation circuit CC may be provided in the subpixel SPA or SPB to compensate for the threshold voltage of the second transistor T2, etc. The compensation circuit CC may include one or more transistors. The compensation circuit CC may include one or more transistors and a capacitor, and may be configured in various ways depending on a compensation method. A pixel including the compensation circuit CC may have various structures, such as 3T1C, 4T2C, 5T2C, 6T1C, 6T2C, and 7T1C. For example, a plurality of transistors may be electrically connected between the second transistor T2 and the light emitting element ED.

FIG. 7 shows a configuration where the second transistor T2 and the light emitting element ED are directly connected to each other, but the embodiments of the invention are not limited thereto. Depending on the form of the compensation circuit CC, the light emitting element ED may further include another transistor or a compensation capacitor between the light emitting element ED and the second transistor T2 that generates drive current.

As needed, the sensor area A and non-sensor area B may include additional components on one side to compensate for resolution differences, or at least one of the transistors or capacitors may be configured differently.

Hereinafter, a display device according to another embodiment of the invention will be described.

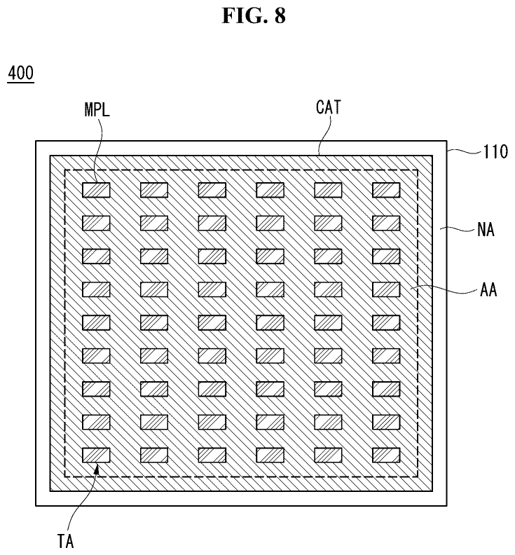

FIG. 8 is a plan view showing a display device according to another embodiment of the invention.

The display device 400 according to the embodiment shown in FIG. 8 includes a display panel 110 having an active area AA and a non-active area NA, a pattern definition layer MPL regularly disposed in the active area AA on the display panel 110, and a cathode CAT disposed in the area excluding the pattern definition layer MPL.

As shown in FIG. 8, the pattern definition layer MPL may be disposed in the active area AA as an island shape, and the cathode CAT may have a matrix shape across the entirety of the active area AA excluding the pattern definition layer MPL. The cathode CAT may be connected to a second power voltage line VSSL supplying a low-potential drive voltage EVSS in the non-active area NA. To this end, the cathode may extend from the outside of the end line of the active area AA to at least a part of the non-active area NA. The cathode CAT may be integrally disposed in contact with the side of the pattern definition layer MPL at least in the active area AA. Referring to FIG. 3, the cathode CAT may be disposed above an intermediate layer EL, and may be disposed overlapping all of a plurality of anodes AND and a bank 150 located between the plurality of anodes AND.

The display device 400 according to FIG. 8 may be used as a transparent display since the entirety of the active area AA can be used as a transmission part.

In the display device 400 according to FIG. 8, the area other than the transmission part TA includes the areas of the emission part EA and non-emission part NEA shown in FIG. 3 and may overlap the cathode CAT.

The cathode CAT and the pattern definition layer MPL contact an electron transport layer ETL, which is the uppermost layer of the intermediate layer, as described above. The electron transport layer ETL includes an electron-transportable organic host EH having a certain LUMO energy level and a metal dopant MD having a work function similar to that of the cathode CAT, thereby having electron transport and electron injection characteristics. Furthermore, the metal dopant is bound to the organic host EH of the electron transport layer ETL, suppressing changes in the surface energy of the pattern definition layer MPL, which prevents a residual layer of the cathode in the transmission part.

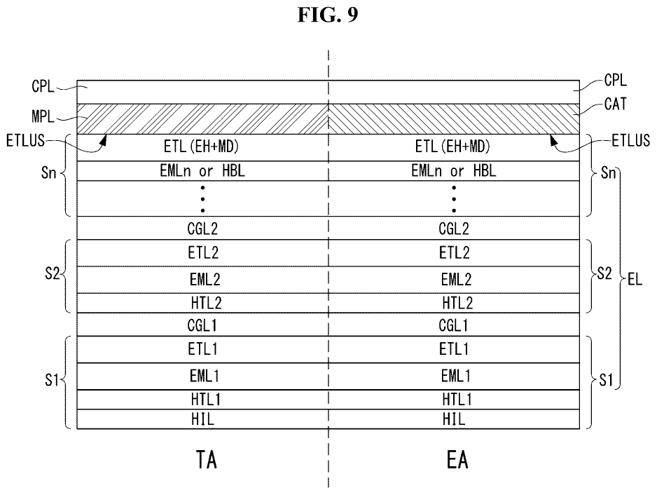

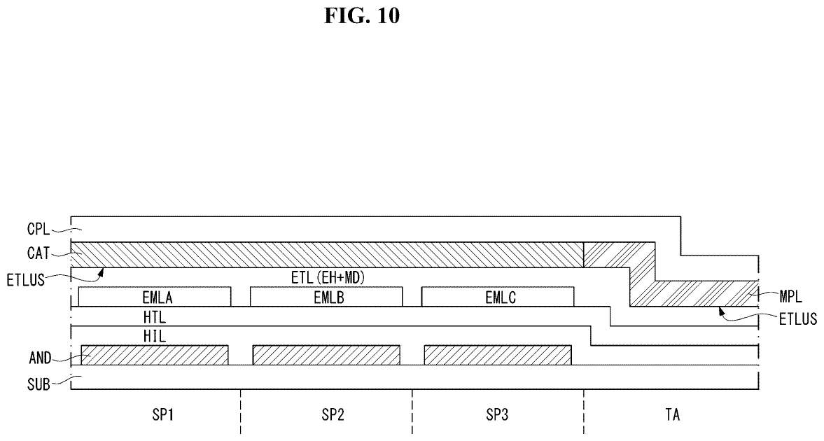

FIGS. 9 and 10 are schematic cross-sectional views showing an emission part and a transmission part in display devices according to various embodiments of the invention.

In the display device of FIG. 9, an intermediate layer EL in the emission part EA and the transmission part TA has a plurality of light emitting stacks S1, S2, . . . , Sn.

As shown in FIG. 9, charge generation layers CGL1, CGL2, . . . are included between the light emitting stacks S1, S2, . . . , Sn. Each of the charge generation layers CGL1 and CGL2 may be independently formed by stacking an n-type charge generation layer and a p-type charge generation layer.

The light emitting stacks S1, S2, . . . , Sn may include hole transport layers HTL1, HTL2, . . . , light emitting layers EML1, EML2, . . . , EMLn, and electron transport layers ETL1, ETL2, . . . , ETL, respectively. The light emitting stack S1 closest to an anode AND may further include a hole injection layer HIL in contact with the anode AND.

In a display device according to an example, the light emitting layers EML1, EML2, . . . , EMLn in different light emitting stacks S1, S2, . . . , Sn may include light emitting layers of the same color in overlapping emission parts. Alternatively, in a display device according to an example, the light emitting layers EML1, EML2, . . . , EMLn in different light emitting stacks S1, S2, . . . , Sn may be configured such that, when the light emitting layer of one light emitting stack in overlapping emission parts, includes a blue light emitting layer, the light emitting layer of another light emitting stack includes a color light emitting layer of a different color from the blue light emitting layer such as a red light emitting layer, a green light emitting layer, and/or a yellow-green light emitting layer. When three or more light emitting stacks S1, S2, . . . , Sn are provided in the display device, the light emitting layers of two or more light emitting stacks may be blue light emitting layers, while the other may be a light emitting layer having a longer wavelength than blue. At least one of the light emitting layers of the light emitting stacks S1, S2, . . . , Sn may include a plurality of light emitting layers. When the light emitting layer of at least one of the light emitting stacks S1, S2, . . . , Sn includes a plurality of light emitting layers, the colors emitted by the plurality of light emitting layers may be the same or different.

When the charge generation layers CGL1 and CGL2 include an n-type charge generation layer and a p-type charge generation layer, the n-type charge generation layer may contact electron transport layers ETL1 and ETL2 of a lower stack. The p-type charge generation layer may contact hole transport layers HTL2, . . . of an upper stack.

In the display device according to this embodiment of the invention, the uppermost layer of the intermediate layer EL is an electron transport layer ETL including an electron-transportable organic host EH and a metal dopant MD, and an upper surface ETLUS of the electron transport layer ETL, which is the uppermost layer of the intermediate layer, may contact a pattern definition layer MPL and a cathode CAT. In addition, a lower surface of the electron transport layer ETL, which is the uppermost layer of the intermediate layer, may contact the light emitting layer EMLn or a hole blocking layer HBL. When defining an intermediate layer EL with the same structure in both the emission part EA and the transmission part TA, as shown in FIG. 9, the lower surface of the electron transport layer ETL, which is the uppermost layer of the intermediate layer, may commonly contact the light emitting layer EMLn or the hole blocking layer HBL in each of the emission part EA and the transmission part TA. If different colored emitting layers are provided in emission parts of subpixels, the lower surface of the electron transport layer ETL, which is the uppermost layer of the intermediate layer, in the emission part EA contacts the light emitting layer EMLn, but in the transmission part TA, the lower surface of the electron transport layer ETL may directly contact the hole transport layer HTL.

A capping layer CPL may be commonly provided on the pattern definition layer MPL and the cathode CAT. The capping layer CPL may include a plurality of capping layers with different refractive indices to enhance the light emission effect.

In a display device according to the embodiment of FIG. 10, first-to-third light emitting layers EML1, EML2, and EML3 that independently exhibit different colors are provided in different subpixels SP1, SP2, and SP3, and the first-to-third light emitting layers EML1, EML2, and EML3 are not provided in a transmission part TA.

Each of the subpixels SP1, SP2, and SP3 commonly includes a light emitting element ED, wherein an anode AND and a cathode CAT are opposite each other, and an intermediate layer EL in which a hole injection layer HIL, a hole transport layer HTL, light emitting layers EML1, EML2, and EML3, and electron transport layer ETL are stacked is provided therebetween. In contrast, the transmission part TA differs in that the light emitting layers EML1, EML2, and EML3 are not provided, as compared to at least the intermediate layers EL of the subpixels SP1, SP2, and SP3. FIG. 10 shows an example in which single light emitting stacks EMLA, EMLB, EMLC are provided between the anode AND and the cathode CAT for each subpixel SP1, SP2, SP3, respectively, but as described in FIG. 9, each of the subpixels SP1, SP2, and SP3 may include a plurality of light emitting stacks and a charge generation layer.

Even in the display devices having the schematic cross-sectional configurations of FIGS. 9 and 10, the cathode CAT of each of the subpixels SP1, SP2, and SP3 and the pattern definition layer MPL of the transmission part TA commonly have an electron transport layer including an electron-transportable organic host EH having a certain LUMO energy level and a metal dopant MD having a work function similar to that of the cathode CAT as the uppermost layer of the intermediate layer.

Therefore, as described above, the electron transport layer ETL of each of the cathode CAT and the pattern definition layer MPL includes an electron-transportable organic host EH having a certain LUMO energy level and a metal dopant MD having a work function similar to that of the cathode CAT, thereby having electron transport and electron injection characteristics. Furthermore, the metal dopant is bound to the organic host EH of the electron transport layer ETL, suppressing changes in the surface energy of the pattern definition layer MPL, which prevents a residual layer of the cathode in the transmission part.

The following experiment was conducted to observe the characteristics of the emission part in the display device according to this embodiment of the invention.

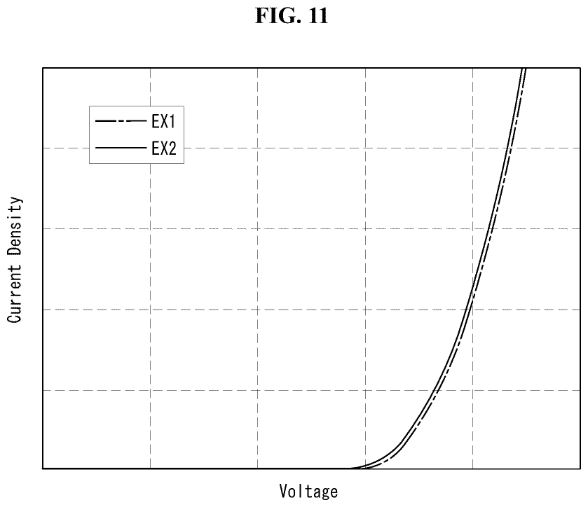

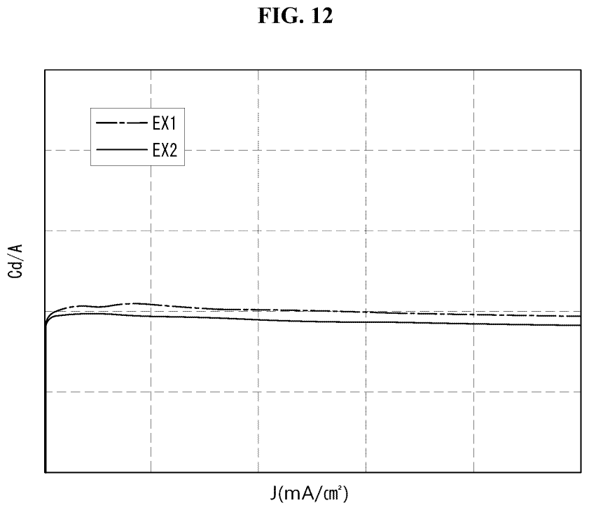

FIG. 11 is a graph showing the I-V characteristics of first and second experimental examples. FIG. 12 is a graph showing the luminance characteristics relative to current density of the first and second experimental examples.

TABLE 1

| Structure of first | Structure of second |
|---|---|
| experimental example (EX1) | experimental example (EX2) |
| AND/HIL/HTL/EML/ETLA/EIL/CAT | AND/HIL/HTL/EML/ETL/CAT |

As shown in Table 1, the light emitting element of the first experimental example (EX1) was formed by stacking an anode AND, a hole injection layer HIL, a hole transport layer HTL, a light emitting layer EML, an electron transport layer ETLA made of a benzimidazole compound, an electron injection layer EIL made of a mixture of ytterbium and LiF, and a cathode CAT made of an AgMg alloy on a transparent substrate.

The light emitting element of the second experimental example (EX2) was formed by including components from an anode AND to an light emitting layer EML in the same manner as in the first experimental example (EX1) and stacking an electron transport layer ETL including an organic host made of phenanthrolinyl and a metal dopant made of lithium, as shown in FIG. 6A, and a cathode CAT in contact with the electron transport layer ETL and made of an AgMg alloy on the light emitting layer EML.

It can be seen from the second experimental example (EX2) that a smaller drive voltage is required to implement the same current density as in the first experimental example (EX1), as shown in FIG. 11, due to electron donating properties and high electron mobility of the organic host even without an electron injection layer, and the luminance characteristics relative to current density are uniformly maintained, as shown in FIG. 12.

That is, in the display device according to this embodiment of the invention, an organic host having a certain LUMO energy level and excellent electron transport properties is used as the main material for the electron transport layer, which is the uppermost layer of the intermediate layer contacting the cathode without an electron injection layer including a separate inorganic compound for electron injection characteristics, whereby it is possible to secure driving characteristics without degrading the properties of the light emitting element.

In the display device according to this embodiment of the invention, a separate material for forming the electron injection layer is not added, and a single electron transport layer has both electron transport and electron injection functions, which enables material savings, eliminates the need for a deposition chamber, and reduces the greenhouse effect generated during a deposition process, whereby a more environmentally friendly structural design is possible and thus ESG (environmental/social/governance) goals may be achieved.

The following experiment was conducted to observe the characteristics of the transmission part in the display device according to the embodiment of the invention.

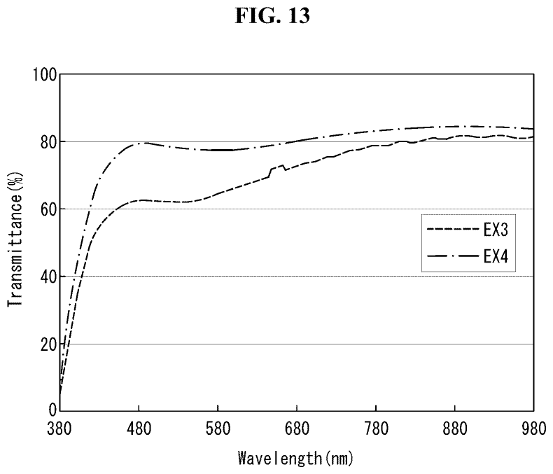

FIG. 13 is a graph showing the transmittance of third and fourth experimental examples for comparison.

TABLE 2

| Structure of third | Structure of fourth |
|---|---|
| experimental example (EX3) | experimental example (EX4) |
| SUB/HIL/HTL/EML/ETLA/EIL/MPL | SUB/HIL/HTL/EML/ETL/MPL |

The transmission part includes no cathode and a pattern definition layer. As shown in Table 2, the transmission part of the third experimental example (EX3) has a structure in which a hole injection layer HIL, a hole transport layer HTL, a light emitting layer EML, an electron transport layer ETLA made of a benzimidazole compound, an electron injection layer EIL made of a mixture of ytterbium (Yb) and LiF, and a pattern definition layer MPL are sequentially stacked on a transparent substrate SUB.

The light emitting element of the fourth experimental example (EX4) was formed by including components from a transparent substrate SUB to a light emitting layer EML in the same manner as in the third experimental example (EX3) and stacking an electron transport layer ETL including an organic host made of phenanthrolinyl and a metal dopant made of lithium, as shown in FIG. 6A, and a pattern definition layer MPL in contact with the electron transport layer ETL on the light emitting layer EML.

As shown in FIG. 13, it can be seen that the third experimental example (EX3) exhibits lower transmittance within a visible wavelength range than the fourth experimental example (EX4). This is because ytterbium (Yb) and LiF in the electron injection layer EIL change the surface energy of the pattern definition layer MPL, whereby a residual layer of the cathode is generated on an upper surface of the pattern definition layer MPL, thereby reducing the transmittance.

In the display device according to this embodiment of the invention, the emission part has the structure of the second experimental example (EX2) and the transmission part has a structure equivalent to that of the fourth experimental example (EX4), thereby providing the following effects. That is, in the display device according to this embodiment of the invention, commonly for both the transmission part and the emission part, an organic host having a certain LUMO energy level and excellent electron transport characteristics is used as the main material for the electron transport layer, which is the uppermost layer of the intermediate layer in contact with the cathode, without an electron injection layer including an inorganic compound, and the metal dopant is bound to a certain site of the organic host such that the metal dopant suppresses changes in the surface energy properties of the pattern definition layer, thereby securing a certain transmittance within a visible wavelength range.

In the display device according to this embodiment of the invention, therefore, it is possible to secure the element characteristics of the emission part and to improve transmittance by differing the composition of uppermost layer of the intermediate layer in contact with the cathode and the pattern definition layer in the structure in which the cathode is defined by providing the pattern definition layer in the transmission part.

As is apparent from the above description, in a display device according to embodiments of the invention, it is possible to define a position of a cathode using a pattern definition layer without using a separate fine metal mask.

In the display device according to embodiments of the invention, it is possible to suppress changes in the surface energy of the pattern definition layer by using an electron-transportable organic host with a LUMO energy level within a certain range as the main material of the uppermost layer of an intermediate layer in contact with the pattern definition layer and the cathode. This may prevent a residual layer of the cathode from remaining on the pattern definition layer.

In the display device according to embodiments of the invention, it is possible to effectively prevent changes in the characteristics of the pattern definition layer caused by the diffusion of a metal dopant by binding the metal dopant to the organic host to prevent the influence of metal dopant diffusion in the uppermost layer of the intermediate layer, thereby preventing the occurrence of the residual layer of the cathode in the area where the pattern definition layer is disposed and thus improving transmittance.

In the display device according to embodiments of the invention, it is possible to improve the sensing sensitivity of a sensor member by providing the area where the cathode is not disposed in the area where the sensor member is disposed when applying the pattern definition layer to the area where the sensor member is disposed.

In the display device according to embodiments of the invention, the visibility of a background image or an object is easy when a transmission part is uniformly disposed on the display device, whereby it is possible to implement a display device having improved transmittance.

In the display device according to embodiments of the invention, it is possible to secure luminous characteristics without changes in luminance characteristics due to increases in drive voltage or current density, even in a structure not including an electron injection layer.

In the display device according to embodiments of the invention, it is possible to conserve materials and to omit a deposition process and a deposition chamber by omitting an electron injection layer, thereby reducing greenhouse gas emissions. Therefore, the display device may be implemented in a more environmentally friendly manner.

In the display device according to embodiments of the invention, it is possible to ultimately prevent a residual layer of the cathode, enabling improved transmittance, and environmentally friendly design is possible, whereby ESG (environmental/social/governance) goals may be achieved.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a substrate comprising:
a display area comprising a first area and a second area; and
a non-display area outside the display area;
a plurality of anodes disposed in the first area, the plurality of anodes being spaced apart from each other;
an intermediate layer disposed on the plurality of anodes, the intermediate layer disposed over an entirety of the display area;
a cathode disposed in the first area to be opposite to the plurality of anodes with the intermediate layer interposed therebetween; and
a pattern definition layer disposed on the intermediate layer in the second area, the pattern definition layer being in contact with a side surface of the cathode,
wherein:
the intermediate layer comprises a plurality of layers; and
an uppermost layer of the intermediate layer is in contact with the cathode and the pattern definition layer, the uppermost layer comprising an electron-transportable organic host and a metal dopant.

2. The display device according to claim 1, wherein an amount of the organic host is greater than an amount of the metal dopant in the uppermost layer of the intermediate layer.

3. The display device according to claim 2, wherein:
the metal dopant is included in the uppermost layer of the intermediate layer in a range of substantially 0.001 wt % to substantially 10 wt %, and the organic host is included in the uppermost layer of the intermediate layer in a range of substantially 90 wt % to substantially 99.999 wt %.

4. The display device according to claim 1, wherein:
the organic host in the uppermost layer of the intermediate layer has a lowest unoccupied molecular orbital (“LUMO”) energy level of substantially −3.5 eV to substantially −2.0 eV; and
the uppermost layer of the intermediate layer has a LUMO energy level of substantially −3.3 eV to substantially −2.0 eV.

5. The display device according to claim 3, wherein:
the cathode has a work function of substantially 4.0 eV or less; and
the work function of the cathode is equal to or is different by substantially 1 eV or less from an absolute value of a LUMO energy level of the uppermost layer of the intermediate layer.

6. The display device according to claim 1, wherein:
the cathode is a metal or a metal alloy comprising at least one of silver (Ag), gold (Au), platinum (Pt), palladium (Pd), copper (Cu), magnesium (Mg), aluminum (Al), titanium (Ti), tungsten (W), and molybdenum (Mo); and
a work function of the cathode is equal to or is different from an absolute value of a LUMO energy level of the uppermost layer of the intermediate layer by substantially 1 eV or less.

7. The display device according to claim 1, wherein the metal dopant comprises an alkali metal or an alkaline earth metal having a work function of substantially 3.0 eV or less.

8. The display device according to claim 1, wherein:
the pattern definition layer does not overlap the first area; and
surface energy of the uppermost layer of the intermediate layer at the first area exposed from the pattern definition layer is greater than surface energy of the pattern definition layer.

9. The display device according to claim 1, wherein the organic host comprises phenanthrolinyl or phenanthrollinylene.

10. The display device according to claim 1, wherein:
the intermediate layer comprises a hole injection layer, a hole transport layer, and an electron transport layer;
a light emitting layer is further provided in at least the first area between the hole transport layer and the electron transport layer; and
the electron transport layer is the uppermost layer of the intermediate layer.

11. The display device according to claim 1, wherein:
the intermediate layer comprises two or more light emitting stacks and a charge generation layer disposed between two adjacent light emitting stacks;
each of the two or more light emitting stacks comprises a hole transport layer, a light emitting layer, and an electron transport layer; and
the electron transport layer of the light emitting stack closest to the cathode is the uppermost layer of the intermediate layer.

12. The display device according to claim 1, wherein:
the intermediate layer comprises two or more light emitting stacks and a charge generation layer provided between two adjacent light emitting stacks;
each of the two or more light emitting stacks comprises a hole transport layer and an electron transport layer;
a light emitting layer is provided between the hole transport layer and the electron transport layer to correspond to different emission parts two-dimensionally spaced apart from each other in the first area; and
the electron transport layer of the light emitting stack closest to the cathode is the uppermost layer of the intermediate layer.

13. The display device according to claim 10, further comprising a hole blocking layer disposed between the light emitting layer and the electron transport layer, the hole blocking layer comprising a different electron-transportable material from the organic host.

14. The display device according to claim 11, further comprising a hole blocking layer disposed between the light emitting layer and the electron transport layer, the hole blocking layer comprising a different electron-transportable material from the organic host.

15. The display device according to claim 12, further comprising a hole blocking layer disposed between the light emitting layer and the electron transport layer, the hole blocking layer comprising a different electron-transportable material from the organic host.

16. The display device according to claim 1, further comprising a capping layer disposed on the pattern definition layer and the cathode.

17. The display device according to claim 1, further comprising:
a sensor member arranged under the substrate to correspond to the second area; and
a thin film transistor arranged in the first area and between the substrate and each of the plurality of anodes.

18. The display device according to claim 1, wherein the first area further comprises a bank exposing a plurality of emission parts while covering an edge of each of the plurality of anodes.

19. The display device according to claim 1, wherein the cathode is integral in the first area, and overlaps a bank located over an entirety of the plurality of anodes and a bank between the plurality of anodes.

20. The display device according to claim 1, wherein the pattern definition layer is disposed in the display area as an island shape, and the cathode is disposed in the display area as a matrix shape excluding the pattern definition layer.
